(19) United States
(12) Patent Application Publication
(10) Pub. No.: US 2012/0034716 A1
(43) Pub. Date: Feb. 9, 2012

(54) METHOD FOR MANUFACTURING LIGHT EMITTING DIODE

(75) Inventor: SHEN-BO LIN, Hukou (TW)

(73) Assignee: ADVANCED OPTOELECTRONIC TECHNOLOGY, INC., Hsinchu Hsien (TW)

(21) Appl. No.: 13/034,619

(22) Filed: Feb. 24, 2011

(30) Foreign Application Priority Data
Aug. 4, 2010 (CN) 201010243860.X

(51) Int. Cl. H01L 33/50; H01L 33/56

(52) U.S. Cl. 438/27; 438/26; 257/E33.066; 257/E33.059

(57) ABSTRACT

A method for manufacturing a light emitting diode includes steps: providing a base having leads formed thereon; fixing a light emitting die on the leads; disposing a glass encapsulant on the base; co-firing the encapsulant with the base to fix them together. The base is made of silicon or ceramic. The encapsulant has a cover covering the light emitting die received in a groove of the base and a positioning plate fittingly engaging into the groove in one embodiment. The encapsulant has a cavity receiving the light emitting die to cover the light emitting die fixed on a top face of the base in another embodiment. Various mechanisms are used to protect the light emitting die during co-firing of the encapsulant and the base.

### BACKGROUND

1. Technical Field

The present disclosure relates to a method for manufacturing a light emitting diode.

2. Description of Related Art

As new type light source, LEDs are widely used in various applications. An LED often includes a die to emit light, a substrate supporting the die, a pair of leads connected to the die to transfer power to the die, and an encapsulant covering the die to protect the die from the outside environment. In order to allow the light emitted from the die to transmit to the outside environment, the encapsulant is generally made of transparent epoxy. However, the epoxy is prone to become yellow when subjects to a high temperature or after a long period of use, affecting the color of the light output from the LED. Therefore, glass is introduced to make the encapsulant so as to substitute the epoxy. Different from the epoxy encapsulant which can be directly molded on the substrate, the glass encapsulant should be made firstly and then fixed to the substrate via adhesive. Nevertheless, the glass and the substrate generally are heterogeneous structures, stress variation between the glass encapsulant and the substrate cannot well-match each other when the glass encapsulant and the substrate subject to a high temperature. Furthermore, the adhesive is easy to deteriorate when subjects to the high temperature, which raises a risk of damage of the LED.

What is needed, therefore, is a method for manufacturing a light emitting diode which can overcome the limitations described above.

### BRIEF DESCRIPTION OF THE DRAWINGS

Many aspects of the present disclosure can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 shows a first step of a process for manufacturing an LED in accordance with a first embodiment of the present disclosure.

FIG. 2 shows a second step of the process for manufacturing the LED in accordance with the first embodiment of the present disclosure.

FIG. 3 shows a third step of the process for manufacturing the LED in accordance with the first embodiment of the present disclosure.

FIG. 4 shows a forth step of the process for manufacturing the LED in accordance with the first embodiment of the present disclosure.

FIG. 5 shows a fifth step of the process for manufacturing the LED in accordance with the first embodiment of the present disclosure.

FIG. 6 shows an individual LED formed in accordance with the first embodiment, which has been manufactured after the step shown in FIG. 5.

FIG. 7 is a view similar to FIG. 5, showing an LED to be manufactured in accordance with a second embodiment of the present disclosure.

FIG. 8 is a view similar to FIG. 5, showing an LED to be manufactured in accordance with a third embodiment of the present disclosure.

FIG. 9 is a view similar to FIG. 3, showing an LED to be manufactured in accordance with a forth embodiment of the present disclosure.

FIG. 10 is a view similar to FIG. 3, showing an LED to be manufactured in accordance with a fifth embodiment of the present disclosure.

### DETAILED DESCRIPTION OF THE EMBODIMENTS

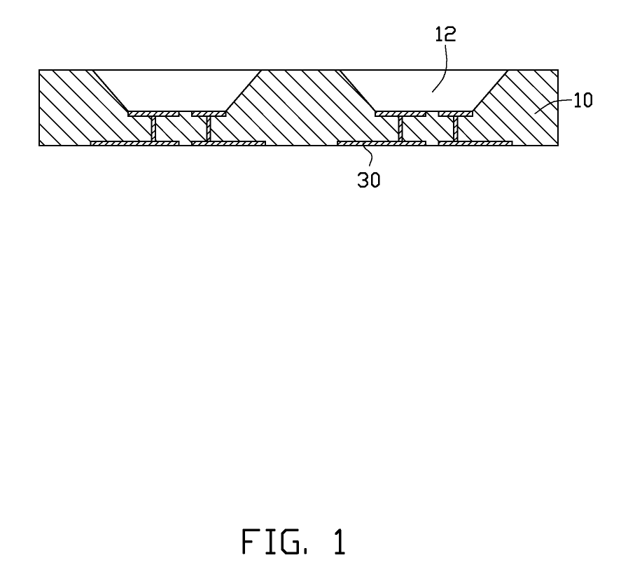

Referring to FIGS. 1-6, steps of a process for manufacturing an LED (light emitting diode) in accordance with a first embodiment of the present disclosure are disclosed.

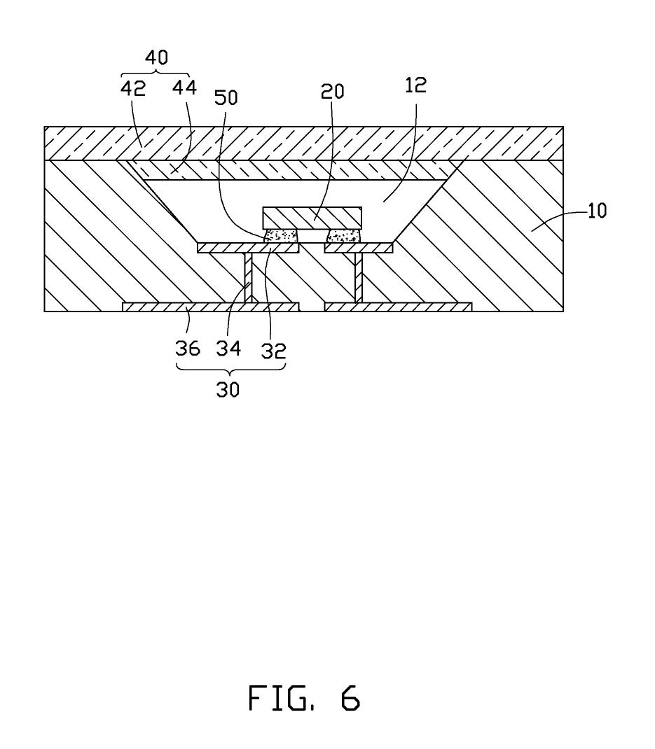

Firstly, a base 10 having a plurality of pairs of leads 30 is provided as shown in FIG. 1. The base 10 may be made of Si or ceramic such as Al₂O₃ or AlN. The base 10 has a plurality of grooves 12 defined in a top face thereof. Each groove 12 has an inner diameter gradually increasing from a bottom towards a top of the base 10. Each pair of leads 30 are formed within the base 10 corresponding to each groove 12. Each lead 30 is made of electrically conductive materials such as copper, silver or gold. Each lead 30 includes a first conductive portion 32, a second conductive portion 36 parallel to the first conductive portion 32 and a connecting portion 34 connecting the first conductive portion 32 with the second conductive portion 36 (see FIG. 6). The first conductive portion 32 of the lead 30 is located at a bottom of a corresponding groove 12 and has a top face exposed within the groove 12. The second conductive portion 36 of the lead 30 is located at a bottom of the base 10 and has a bottom face exposed. The connecting portion 34 is perpendicular to the first and second conductive portions 32, 36 and substantially received within the base 10.

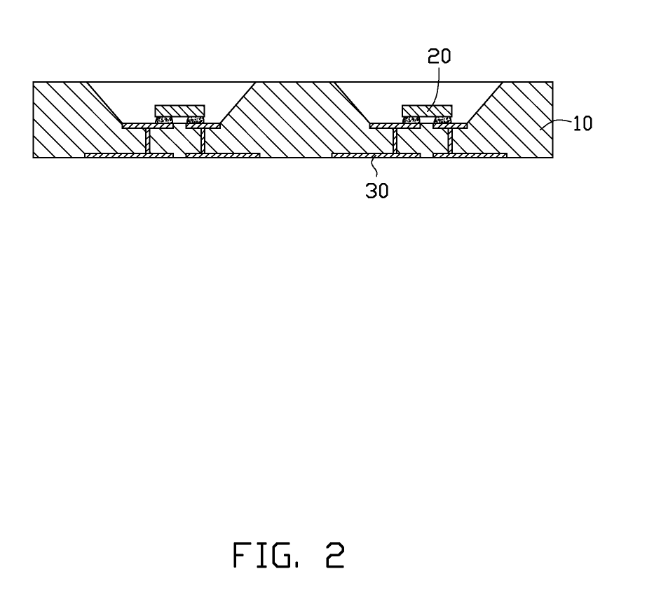

Then a plurality of light emitting dies 20 are fixed on the leads 30 as shown in FIG. 2, respectively. The light emitting dies 20 are preferably mounted on the leads 30 by flip chip bonding for increasing a light extracting efficiency of the LED. Each light emitting die 20 may be made of GaN, AlGaN, AlInGaN or other suitable light emitting materials. The light emitting die 20 can emit light by driven of current conducted from the leads 30. Each light emitting die 20 is received in a corresponding groove 12 and connected to the two first conductive portions 32 of one corresponding pair of leads 30 via electrically conductive interconnection 50 (see FIG. 6). The electrically conductive interconnection 50 can be electrically conductive adhesive or solder balls. The electrically conductive adhesive may be epoxy doped with silver particulates for providing good electrical conduction between the light emitting die 20 and the leads 30.

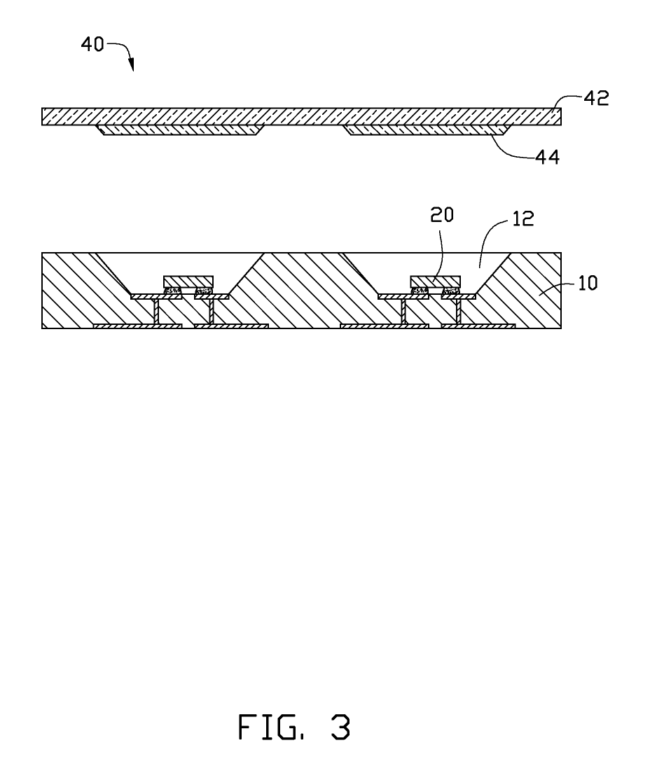

An encapsulant 40 is further disposed on the base 10 to seal the light emitting dies 20 within the grooves 12 as shown in FIG. 3. The encapsulant 40 is made of transparent glass composed of SiO₂, Na₂O.SiO₂ or other suitable materials. The encapsulant 40 includes a cover 42 and a plurality of positioning plates 44 formed on a bottom face of the cover 42. The cover 42 may be made integrally with the positioning plates 44 by casting or machining of an individual stock, or made separately from the positioning plates 44 and fixed with the positioning plates 44 via co-firing or adhering. The cover 42 has a size similar to that of the base 10 so that the cover 42 can substantially overlay an entire area of the top face of the base 10. Each positioning plate 44 has a thickness smaller than that of the cover 42 and a width gradually decreasing along a top-to-bottom direction. Each positioning plate 44 is fittingly received in a top of the groove 12 to thereby position the cover 42 on the base 10.

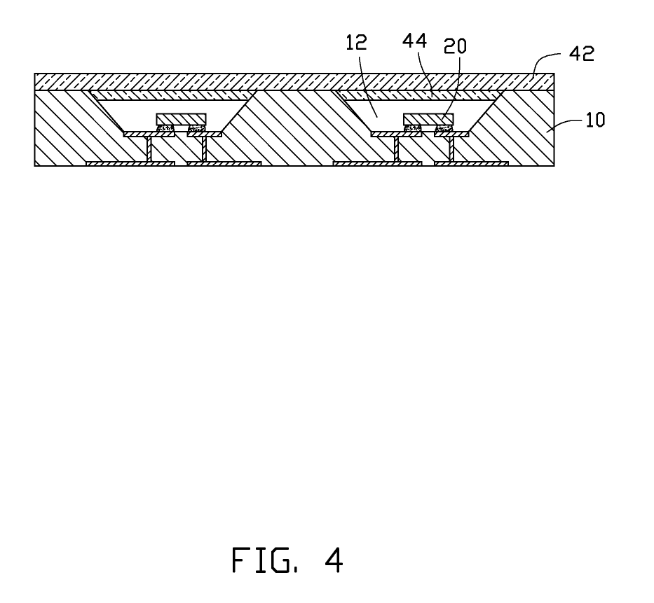

The base 10 and the encapsulant 40 are securely fixed to each other by co-firing as shown in FIG. 4. A temperature during co-firing is preferably selected between 300 and 500 for promoting joint of the encapsulant 40 to the base 10. Furthermore, in order to lower the temperature of co-firing for protecting the light emitting dies 20, a liquid glass (i.e., sodium silicate, not shown) can be smeared between the encapsulant 40 and the base 10 before the co-firing. In addition, noble gas can be filled within the grooves 12 so as to protect the light emitting dies 20 from destroy due to outside dust or moisture entering the grooves 12. The connection between the base 10 and the encapsulant 40 under co-firing is reliable, secure and firm, whereby the LED can have a stable structure to resist a high working temperature.

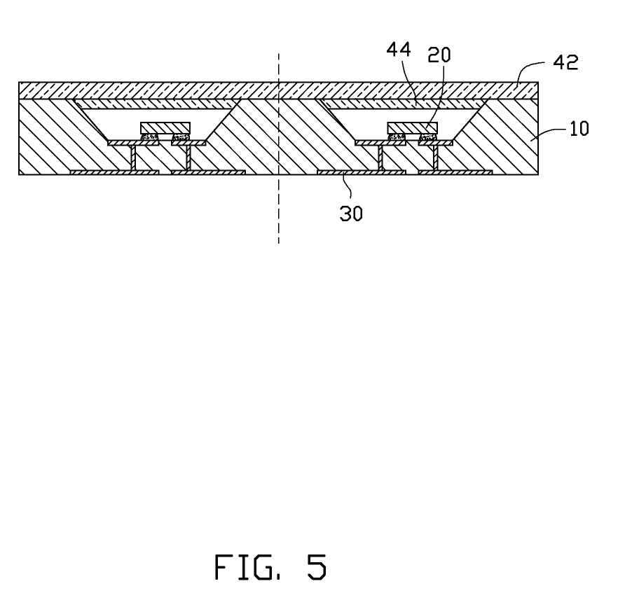

Finally, the base 10 and the encapsulant 40 are diced into a plurality of individual LEDs along areas between adjacent grooves 12 as shown in FIG. 5. The above process of firstly packing and then dicing can simplify manufacturing processes of the LEDs, thereby facilitating rapid mass production of the LEDs.

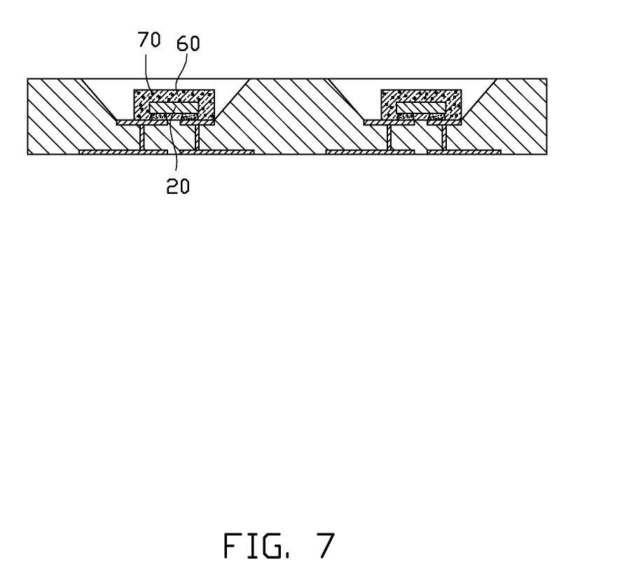

Since the light emitting die 20 is easily to be damaged under a high temperature, in order to further reduce possibility of damage to the light emitting die 20 during co-firing, a transparent protective layer 60 can be formed around the light emitting die 20 before co-firing. As shown in FIG. 7, the protective layer 60 substantially covers the light emitting die 20 and coupled with the leads 30 and the base 10. The protective layer 60 may be liquid epoxy dispensed on the light emitting die 20 and then baked to harden. A thickness of the protective layer 60 should be controlled within a range so that the protective layer 60 would not block the positioning plate 44 received in the groove 12. Preferably, the protective layer 60 is spaced a gap from a bottom face of the positioning plate 44 of the encapsulant 40. Alternatively, the protective layer 60 can have phosphors doped therein for changing color of the light emitted from the light emitting die 20. The phosphors may be made of garnet compound, silicate, nitride or other suitable materials, depending on the actual requirement of the color. The light excited from the phosphors mixes with the light directly emitted from the light emitting die 20 to have a desirable color.

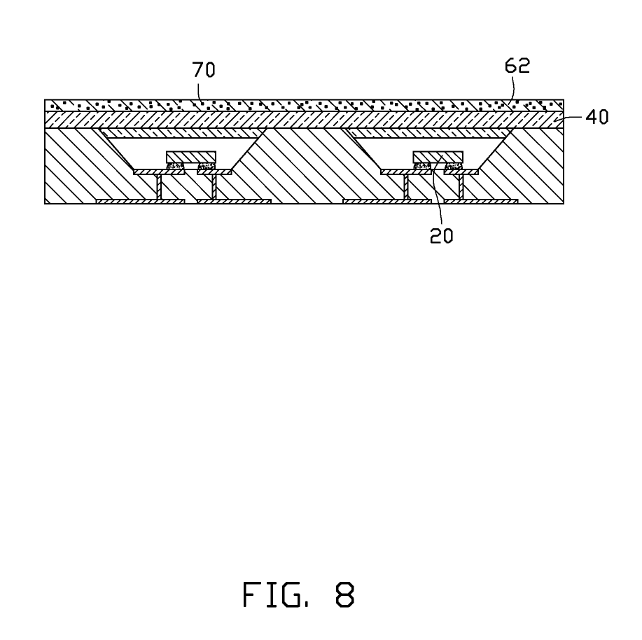

The phosphors can also be placed on other locations of the LED. For example, the phosphors may be doped within one or both of the cover 42 and the positioning plate 44, or in the form of a single layer adhered on a top face of the cover 42 or a bottom face of the positioning plate 44. FIG. 8 shows the phosphors being dispersed in a layer (not labeled) secured to the top face of the cover 42 as an example. The location of the phosphors remote from the light emitting die 20 can prevent chromatic dispersion from occurring when the mixed light transmits through the encapsulant 40.

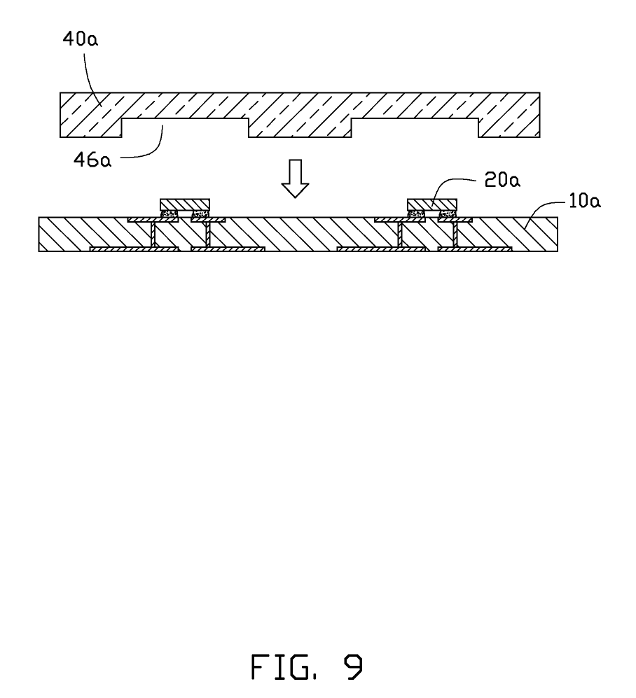

For meeting thickness requirements of thin products, the structure of the LED can be varied to have a small thickness as shown in FIG. 9. The differences between the LEDs of this embodiment and the previous embodiments are the base 10a and the encapsulant 40a. The base 10a has a flat top face without grooves 12 defined therein, and the light emitting dies 20a are mounted on the top face of the base 10a. The encapsulant 40a defines a plurality of cavities 46a in a bottom face thereof corresponding to the light emitting dies 20, respectively. The light emitting dies 20a are received in the cavities 46a of the encapsulant 40a to be protected by the encapsulant 40a. It is noted that the encapsulant 40a and the base 10a are also fixed to each other by co-firing in this embodiment.

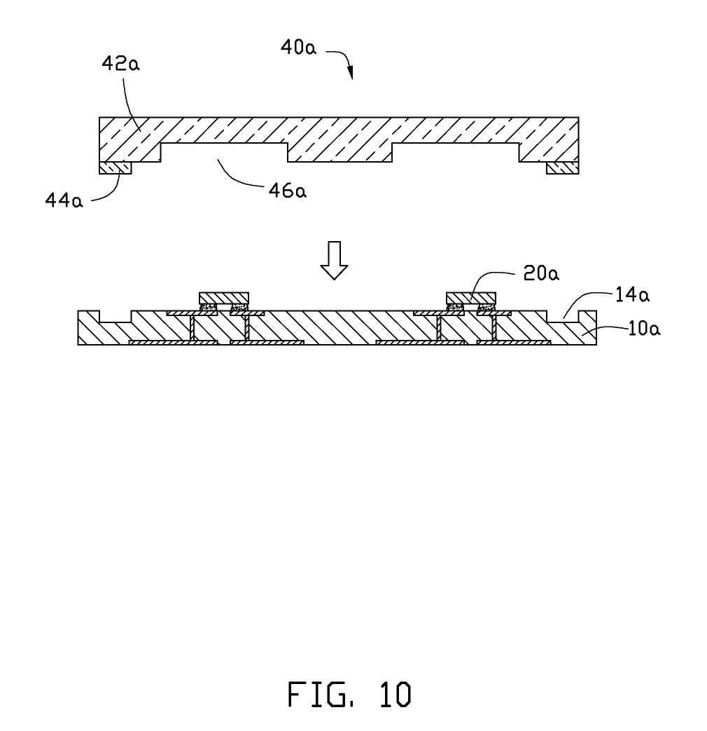

Referring to FIG. 10, in order to realize convenient position between the encapsulant 40a and the base 10a before co-firing, the encapsulant 40a can form a plurality of protrusions 44a on the bottom face of a cover 42a thereof, and the base 10a can form a plurality of holes 14a in the top face thereof corresponding to the protrusions 44a, respectively. The protrusions 44a are retained in the holes 14a, respectively, whereby the encapsulant 40a is able to accurately cover the light emitting dies 20a by the guidance of the protrusions 44a. The protrusions 44a can further enhance joint strength between the encapsulant 40a and the base 10a by engagement into the holes 14a. The protrusions 44a may be made integrally with or separately from the cover 42a in a manner as that of the positioning plates 44 disclosed in accordance with the first embodiment.

It is believed that the present disclosure and its advantages will be understood from the foregoing description, and it will be apparent that various changes may be made thereto without departing from the spirit and scope of the present disclosure or sacrificing all of its material advantages, the examples hereinbefore described merely being preferred or exemplary embodiments.

What is claimed is:

1. A method for manufacturing an LED (light emitting diode), comprising steps of:
providing a base having two leads formed thereon;
fixing a light emitting die on the base and electrically connecting the light emitting die with the leads;
disposing a glass encapsulant on the base; and
fixing the encapsulant with the base by co-firing.

2. The method as claimed in claim 1, wherein each of the leads comprises a first conductive portion connected to the light emitting die, a second conductive portion located at a bottom face of the base and a connecting portion connecting the first conductive portion with the second conductive portion.

3. The method as claimed in claim 2, wherein the light emitting die is fixed to the first conductive portions of the leads by flip chip bonding.

4. The method as claimed in claim 1, wherein the encapsulant comprises a cover having a bottom face in contact with a top face of the base.

5. The method as claimed in claim 4, wherein the base defines a groove in the top face thereof to receive the light emitting die.

6. The method as claimed in claim 5, wherein the encapsulant comprises a positioning plate extending downwardly from the bottom face of the cover, the positioning plate being fittingly received in a top portion of the groove.

7. The method as claimed in claim 6, wherein the positioning plate is fixed to the cover by co-firing.

8. The method as claimed in claim 4, wherein the cover defines a cavity in the bottom face thereof to receive the light emitting die.

9. The method as claimed in claim 8, wherein the base has a hole defined in the top face thereof, and the encapsulant has a protrusion extending downwardly from the bottom face of the cover, the protrusion being received in the hole.

10. The method as claimed in claim 1, wherein a protective layer is formed around the light emitting die before disposing the encapsulant on the base.

11. The method as claimed in claim 10, wherein the protective layer is spaced a gap from the encapsulant.

12. The method as claimed in claim 11, wherein the protective layer is transparent epoxy which is firstly dispensed on the light emitting die in liquid and then baked to harden.

13. The method as claimed in claim 12, wherein the protective layer has phosphors doped therein.

14. The method as claimed in claim 1, wherein the encapsulant has phosphors doped therein.

15. The method as claimed in claim 1, wherein the encapsulant has phosphors doped in a layer adhered on a surface thereof.

16. The method as claimed in claim 1, wherein noble gas is filled between the encapsulant and the base to protect the light emitting die prior to fixing the encapsulant with the base by co-firing.

17. The method as claimed in claim 1, wherein a liquid glass is smeared between the encapsulant and the base before fixing the encapsulant to the base by co-firing.

18. The method as claimed in claim 1, wherein the base is made of silicon or ceramic.
